(19) United States
(12) Patent Application Publication
(10) Pub. No.: US 2011/0223770 A1
(43) Pub. Date: Sep. 15, 2011

(54) NITRIDE PLASMA ETCH WITH HIGHLY TUNABLE SELECTIVITY TO OXIDE

(75) Inventors: Alan Jensen, White Salmon, CA (US); Mayumi Block, Sunnyvale, CA (US)

(73) Assignee: LAM RESEARCH CORPORATION, Fremont, CA (US)

(21) Appl. No.: 12/724,100

(22) Filed: Mar. 15, 2010

(51) Int. Cl. H01L 21/3065; C23F 1/08

(52) U.S. Cl. 438/724; 156/345.26; 257/E21.218

(57) ABSTRACT

A method for selectively etching a nitride layer with respect to a silicon oxide based layer over a substrate is provided. The substrate is placed in a plasma processing chamber. The nitride layer is etched, comprising the steps of flowing a nitride etch gas comprising a hydrocarbon species, an oxygen containing species and a fluorocarbon or hydrofluorocarbon species into the plasma chamber, forming a plasma from the nitride etch gas, and using the plasma from the nitride etch gas to selectively etch the nitride layer with respect to the silicon oxide based layer.

### BACKGROUND OF THE INVENTION

The present invention relates to etching an etch layer through a mask during the production of a semiconductor device. More specifically, the present invention relates to providing a tunable highly selective etch of nitrides, such as silicon nitride, with respect to silicon oxide.

During semiconductor wafer processing, features may be etched into a silicon nitride layer. A silicon oxide layer may be used as an etch mask for the silicon nitride, as an etch stop, or may be part of the device stack that is undesirable to etch.

### SUMMARY OF THE INVENTION

To achieve the foregoing and in accordance with the purpose of the present invention, a method for selectively etching a nitride layer with respect to a silicon oxide based layer over a substrate is provided. The substrate is placed in a plasma processing chamber. The nitride layer is etched, comprising the steps of flowing a nitride etch gas comprising a hydrocarbon species, an oxygen containing species and a fluorocarbon or hydrofluorocarbon species into the plasma chamber, forming a plasma from the nitride etch gas, and using the plasma from the nitride etch gas to selectively etch the nitride layer with respect to the silicon oxide based layer.

In another manifestation of the invention, a method for selectively etching silicon nitride with respect to a silicon oxide based material forming a stack is provided. The stack is placed in a plasma processing chamber. The silicon nitride is etched, comprising the steps of flowing a silicon nitride etch gas into the plasma processing chamber, wherein the silicon nitride etch gas comprises oxygen, a fluorocarbon or hydrofluorocarbon, and CH₄ or C₂H₄, forming a plasma from the silicon nitride etch gas, and using the plasma to selectively etch the silicon nitride with respect to the silicon oxide based material.

In another manifestation of the invention an apparatus for selectively etching a silicon nitride layer with respect to a silicon oxide based layer over a substrate is provided. A plasma processing chamber, comprising a chamber wall forming a plasma processing chamber enclosure, a substrate support for supporting a wafer within the plasma processing chamber enclosure, a pressure regulator for regulating the pressure in the plasma processing chamber enclosure, at least one electrode for providing power to the plasma processing chamber enclosure for sustaining a plasma, a gas inlet for providing gas into the plasma processing chamber enclosure, and a gas outlet for exhausting gas from the plasma processing chamber enclosure is provided, A gas source is in fluid connection with the gas inlet and comprises a CH₄ or C₂H₄ gas source, an oxygen gas source, and a fluorocarbon or hydrofluorocarbon gas source. A controller controllably is connected to the gas source and the at least one electrode, and comprises at least one processor and computer readable media. The computer readable media comprises computer readable code for chucking the substrate to the wafer support, computer readable code for flowing a selectively etching nitride etch gas into the plasma processing chamber, comprising computer readable code for flowing oxygen from the oxygen gas source into the plasma processing chamber, computer readable code for flowing fluorocarbon or hydrofluorocarbon gas from the fluorocarbon or hydrofluorocarbon gas source into the plasma processing chamber, and computer readable code flowing CH₄ or C₂H₄ gas from the CH₄ or C₂H₄ gas source into the plasma processing chamber, and computer readable code for forming the selectively etching nitride etch gas into a plasma to selectively etch the silicon nitride layer with respect to the silicon oxide based layer.

These and other features of the present invention will be described in more detail below in the detailed description of the invention and in conjunction with the following figures.

### BRIEF DESCRIPTION OF THE DRAWINGS

The present invention is illustrated by way of example, and not by way of limitation, in the figures of the accompanying drawings and in which like reference numerals refer to similar elements and in which:

FIG. 1 is a high level flow chart of an embodiment of the invention.

FIGS. 2A-C are schematic views of a stack processed according to an embodiment of the invention.

FIG. 3 is a schematic view of an etch reactor that may be used for etching.

FIGS. 4A-B illustrate a computer system, which is suitable for implementing a controller used in embodiments of the present invention.

FIGS. 5A-B are schematic views of another stack processed according to another embodiment of the invention.

FIGS. 6A-B are schematic views of another stack processed according to another embodiment of the invention.

### DETAILED DESCRIPTION OF THE PREFERRED EMBODIMENTS

The present invention will now be described in detail with reference to a few preferred embodiments thereof as illustrated in the accompanying drawings. In the following description, numerous specific details are set forth in order to provide a thorough understanding of the present invention. It will be apparent, however, to one skilled in the art, that the present invention may be practiced without some or all of these specific details. In other instances, well known process steps and/or structures have not been described in detail in order to not unnecessarily obscure the present invention.

Silicon nitride layers have been selectively etched with respect to silicon oxide using an etch chemistry of a hydrofluorocarbon or fluorocarbon and oxygen providing a selectivity of up to 2:1. Attempts to increase selectivity with such chemistries have caused etch stop, undesirable profile shrink or undesirable profile undercut.

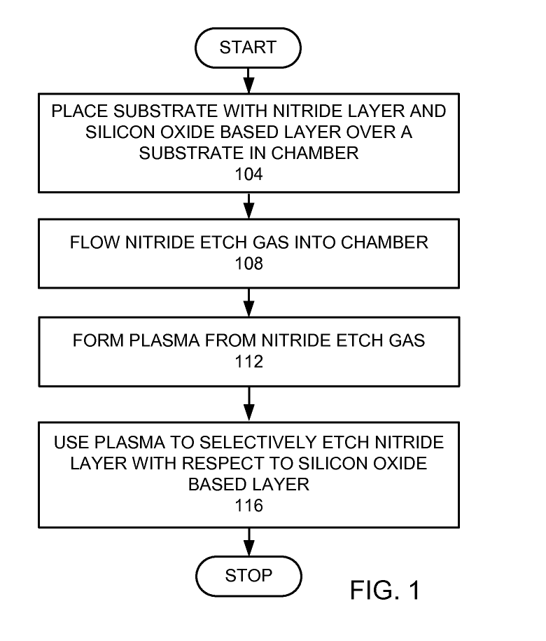

To facilitate understanding, FIG. 1 is a high level flow chart of a process used in an embodiment of the invention. A substrate with a nitride layer and a silicon oxide based layer is placed in a chamber, such as a plasma processing chamber (step 104). The nitride layer is etched using the following steps. A nitride etch gas comprising a hydrocarbon species, an oxygen containing species, and a fluorocarbon or hydrofluorocarbon species is flowed into the chamber (step 108). A plasma is formed from the nitride etch gas (step 112). Features are selectively etched into the nitride layer with respect to the silicon oxide based layer using the plasma from the nitride etch gas (step 116).

### Examples

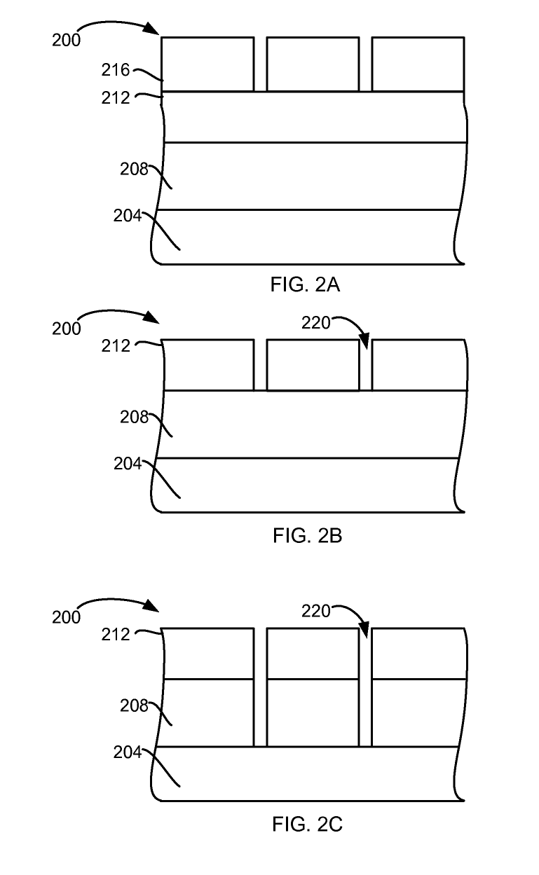

In a first example of the invention, the nitride layer is a silicon nitride layer. In other examples the nitride layer may be another nitride material, such as carbon nitride. FIG. 2A is a cross-sectional view of a stack 200 with a substrate 204 over which a silicon nitride layer 208 is placed, over which a silicon oxide layer 212 is placed, over which a photoresist mask 216 is placed, which may be used in an embodiment of the invention. The silicon oxide based layer 212 is a silicon oxide layer, which may have additional additives, such as organic components to form low-k organosilicate glass. The substrate 204 is placed in an etch chamber or plasma processing chamber (step 104).

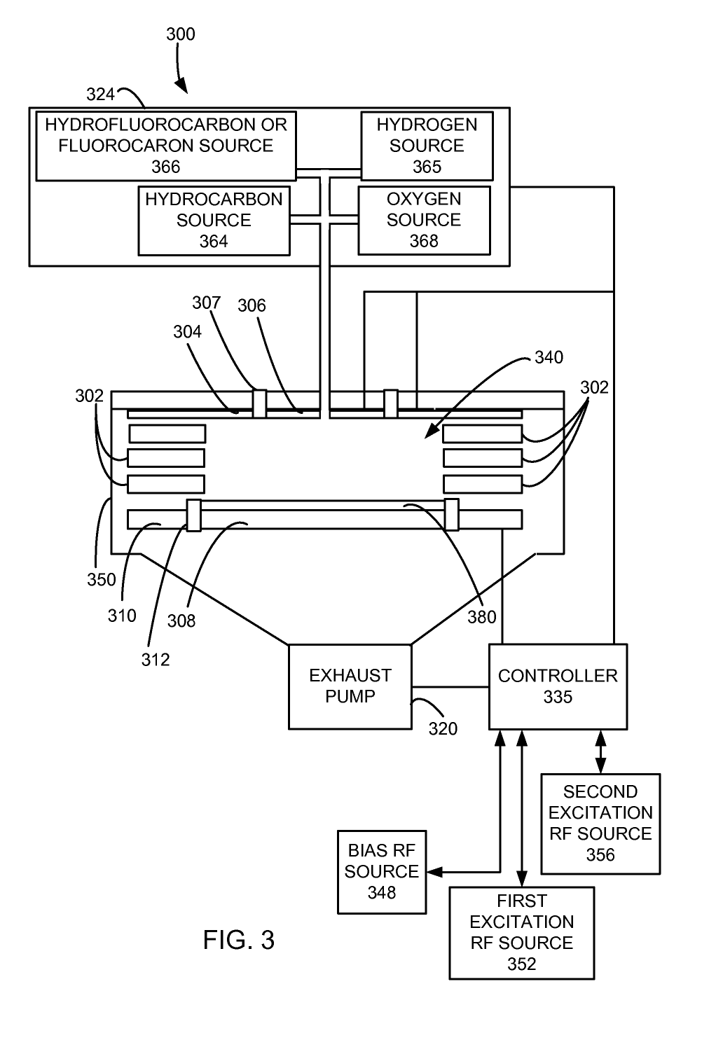

FIG. 3 is a schematic view of an etch reactor that may be used in practicing the invention. In one or more embodiments of the invention, an etch reactor 300 comprises a top central electrode 306, top outer electrode 304, bottom central electrode 308, and a bottom outer electrode 310, within a chamber wall 350. A top insulator ring 307 insulates the top central electrode 306 from the top outer electrode 304. A bottom insulator ring 312 insulates the bottom central electrode 308 from the bottom outer electrode 310. Also within the etch reactor 300, a substrate 380 is positioned on top of the bottom central electrode 308. Optionally, the bottom central electrode 308 incorporates a suitable substrate chucking mechanism (e.g., electrostatic, mechanical clamping, or the like) for holding the substrate 380.

A gas source 324 is connected to the etch reactor 300 and supplies the etch gas into a plasma region 340 of the etch reactor 300 during the etch processes. In this example, the gas source 324 comprises a hydrocarbon source 364, a hydrogen source 365, a hydrofluorocarbon or fluorocarbon source 366, and an oxygen source 368.

A bias RF source 348, a first excitation RF source 352, and a second excitation RF source 356 are electrically connected to the etch reactor 300 through a controller 335 to provide power to the electrodes 304, 306, 308, and 310. The bias RF source 348 generates bias RF power and supplies the bias RF power to the etch reactor 300. Preferably, the bias RF power has a frequency between 1 kilo Hertz (kHz) and 10 mega Hertz (MHz). More preferably, the bias RF power has a frequency between 1 MHz and 5 MHz. Even more preferably, the bias RF power has a frequency of about 3 MHz.

The first excitation RF source 352 generates source RF power and supplies the source RF power to the etch reactor 300. Preferably, this source RF power has a frequency that is greater than the bias RF power. More preferably, this source RF power has a frequency that is between 10 MHz and 40 MHz. Most preferably, this source RF power has a frequency of 27 MHz.

The second excitation RF source 356 generates another source RF power and supplies the source RF power to the etch reactor 300, in addition to the RF power generated by the first excitation RF source 352. Preferably, this source RF power has a frequency that is greater than the bias RF source and the first RF excitation source. More preferably, the second excitation RF source has a frequency that is greater than or equal to 40 MHz. Most preferably, this source RF power has a frequency of 60 MHz.

The different RF signals may be supplied to various combinations of the top and bottom electrodes. Preferably, the lowest frequency of the RF should be applied through the bottom electrode on which the material being etched is placed, which in this example is the bottom central electrode 308.

The controller 335 is connected to the gas source 324, the bias RF source 348, the first excitation RF source 352, and the second excitation RF source 356. The controller 335 controls the flow of the etch gas into the etch reactor 300, as well as the generation of the RF power from the three RF sources 348, 352, 356, the electrodes 304, 306, 308, and 310, and the exhaust pump 320.

In this example, confinement rings 302 are provided to provide confinement of the plasma and gas, which pass between the confinement rings and are exhausted by the exhaust pump. A Flex 45 DS® dielectric etch system made by Lam Research Corporation™ of Fremont, Calif. may be used in a preferred embodiment of the invention.

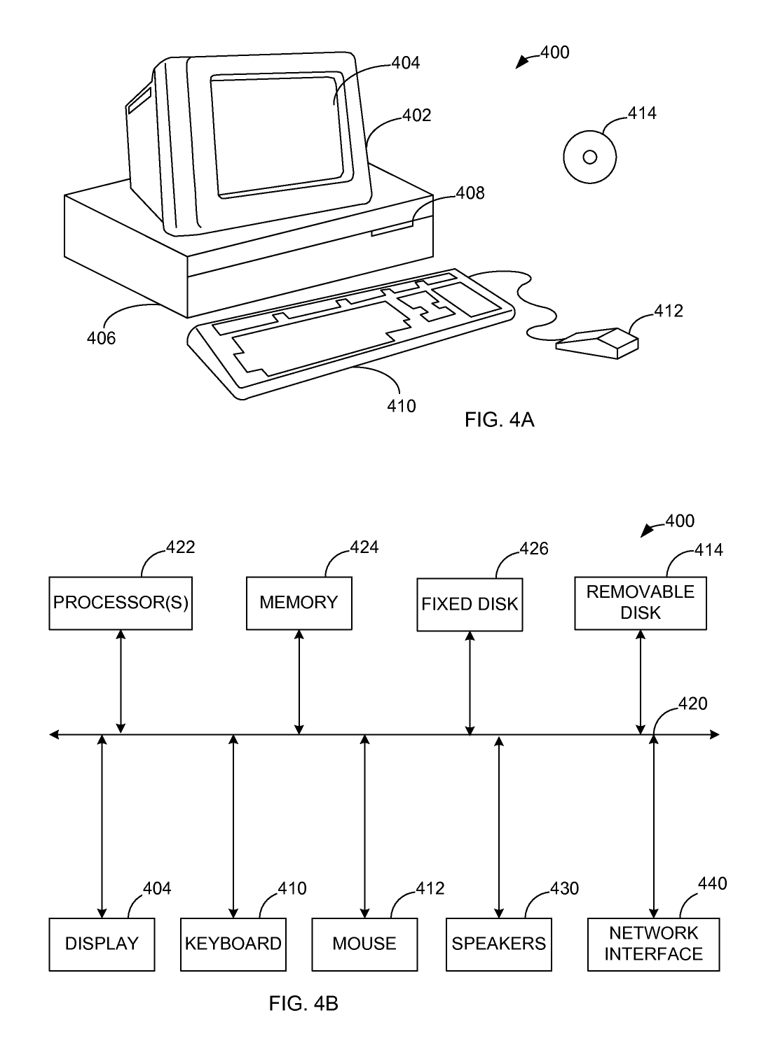

FIGS. 4A and 4B illustrate a computer system, which is suitable for implementing the controller 335 used in one or more embodiments of the present invention. FIG. 4A shows one possible physical form of the computer system 400. Of course, the computer system may have many physical forms ranging from an integrated circuit, a printed circuit board, and a small handheld device up to a huge super computer. Computer system 400 includes a monitor 402, a display 404, a housing 406, a disk drive 408, a keyboard 410, and a mouse 412. Disk 414 is a computer-readable medium used to transfer data to and from computer system 400.

FIG. 4B is an example of a block diagram for computer system 400. Attached to system bus 420 is a wide variety of subsystems. Processor(s) 422 (also referred to as central processing units, or CPUs) are coupled to storage devices, including memory 424. Memory 424 includes random access memory (RAM) and read-only memory (ROM). As is well known in the art, ROM acts to transfer data and instructions uni-directionally to the CPU and RAM is used typically to transfer data and instructions in a bi-directional manner. Both of these types of memories may include any suitable of the computer-readable media described below. A fixed disk 426 is also coupled bi-directionally to CPU 422; it provides additional data storage capacity and may also include any of the computer-readable media described below. Fixed disk 426 may be used to store programs, data, and the like and is typically a secondary storage medium (such as a hard disk) that is slower than primary storage. It will be appreciated that the information retained within fixed disk 426 may, in appropriate cases, be incorporated in standard fashion as virtual memory in memory 424. Removable disk 414 may take the form of any of the computer-readable media described below.

CPU 422 is also coupled to a variety of input/output devices, such as display 404, keyboard 410, mouse 412, and speakers 430. In general, an input/output device may be any of: video displays, track balls, mice, keyboards, microphones, touch-sensitive displays, transducer card readers, magnetic or paper tape readers, tablets, styluses, voice or handwriting recognizers, biometrics readers, or other computers. CPU 422 optionally may be coupled to another computer or telecommunications network using network interface 440. With such a network interface, it is contemplated that the CPU might receive information from the network, or might output information to the network in the course of performing the above-described method steps. Furthermore, method embodiments of the present invention may execute solely upon CPU 422 or may execute over a network such as the Internet in conjunction with a remote CPU that shares a portion of the processing.

In addition, embodiments of the present invention further relate to computer storage products with a computer-readable medium that have computer code thereon for performing various computer-implemented operations. The media and computer code may be those specially designed and constructed for the purposes of the present invention, or they may be of the kind well known and available to those having skill in the computer software arts. Examples of computer-readable media include, but are not limited to: magnetic media such as hard disks, floppy disks, and magnetic tape; optical media such as CD-ROMs and holographic devices; magneto-optical media such as floptical disks; and hardware devices that are specially configured to store and execute program code, such as application-specific integrated circuits (ASICs), programmable logic devices (PLDs) and ROM and RAM devices. Examples of computer code include machine code, such as produced by a compiler, and files containing higher level of code that are executed by a computer using an interpreter. Computer readable media may also be computer code transmitted by a computer data signal embodied in a carrier wave and representing a sequence of instructions that are executable by a processor.

In this example, the silicon oxide based layer 212 is etched in the same etch reactor 300 as the silicon nitride layer 208. A conventional etch chemistry is used to selectively etch the silicon oxide based layer 212 with respect to the photoresist mask 216. FIG. 2B is a cross sectional view of the stack 200 after features 220 have been etched into the silicon oxide based layer 212. In this example, the photoresist mask is removed during the silicon oxide base layer 212 etch. In other embodiments, some photoresist may remain.

The silicon nitride layer 208 is then selectively etched with respect to the silicon oxide based layer 212. A nitride etch gas comprising a hydrocarbon species, a fluorine containing species, and an oxygen containing species is flowed into the etch reactor (step 108). In this example, the nitride etch gas is 5 sccm O₂, 180 sccm H₂, 60 sccm CF₄, 50 sccm CH₄, and 200 sccm Ar. Since this chemistry is used to selectively etch silicon nitride with respect to the silicon oxide based layer, the nitride etch chemistry is different from the etch chemistry used to etch the silicon oxide in the previous step in this example.

A plasma is formed from the nitride etch gas (step 112). To form the plasma, the pressure is set to 80 mTorr. A signal of 50 watts at 27 MHz is provided. A signal of 450 watts at 60 MHz is provided. The conditions are maintained for 20 seconds to allow the plasma to selectively etch the nitride layer with respect to the silicon oxide based layer (step 116). The flow of the nitride etch gas and plasma power is then stopped. Using the above recipe in an experiment for forming contacts found a silicon nitride to silicon oxide selectivity of about 16:1.

FIG. 2C is a cross sectional view of the stack 200 after the flow of the nitride etch gas has been stopped after the silicon nitride layer 208 has been etched. The high selectivity between the silicon nitride layer and the silicon oxide based layer allows for minimal silicon oxide etching during the etching of the silicon nitride layer 208, as shown. Since the silicon oxide layer will form part of the ultimate stack, a high selectivity is desirable.

In this example, the hydrocarbon species was CH₄. In the preferred embodiment the hydrocarbon species is CH₄ or C₂H₄. It is believed that these hydrocarbons provide a high selectivity, without etch stop or loss of profile. In the preferred embodiment, the oxygen containing species is oxygen.

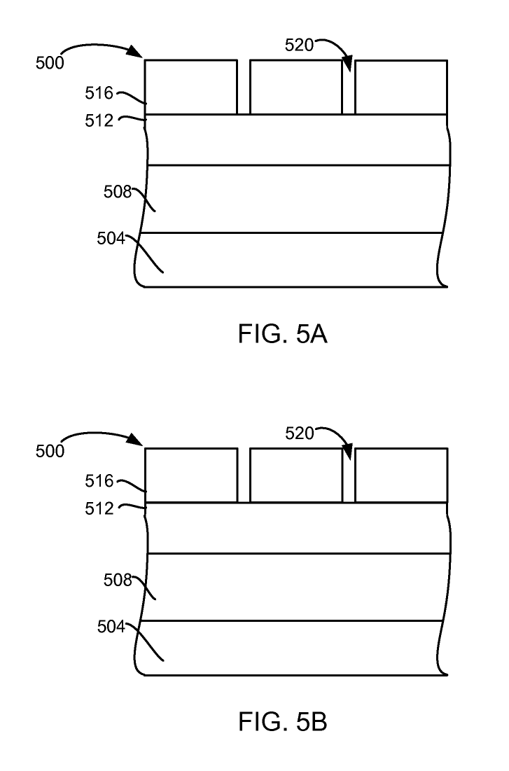

FIG. 5A is a cross sectional view of another stack 500, with a substrate 504 over which a first silicon oxide based layer 508 is disposed, over which a silicon nitride layer 512 is disposed, over which a second silicon oxide based layer 516 is disposed. One ore more intermediate layers may be placed between various layers, such as between the substrate 504 and the first silicon oxide based layer 508. However, the first silicon oxide based layer 508 must be sufficiently close to the silicon nitride layer 512, so that the first silicon oxide based layer 508 acts as an etch stop. In this example, features 520 have already been formed in the second silicon oxide based layer 516.

A selective silicon nitride layer etch is performed In this example, the nitride etch gas is 5 sccm O₂, 180 sccm H₂, 60 sccm CF₄, 50 sccm CH₄, and 200 sccm Ar. The pressure is set to 80 mTorr. A signal of 50 watts at 27 MHz is provided. A signal of 450 watts at 60 MHz is provided. The conditions are maintained for 20 seconds to allow the plasma to selectively etch the nitride layer with respect to the silicon oxide based layer. The flow of the nitride etch gas and plasma power is then stopped.

FIG. 5B is a cross sectional view of the stack 500 after the silicon nitride layer etch is completed. In this example the high selectivity between the silicon nitride layer 512 and the silicon oxide based layers 508, 516, allows the first silicon oxide based layer to act as an etch stop.

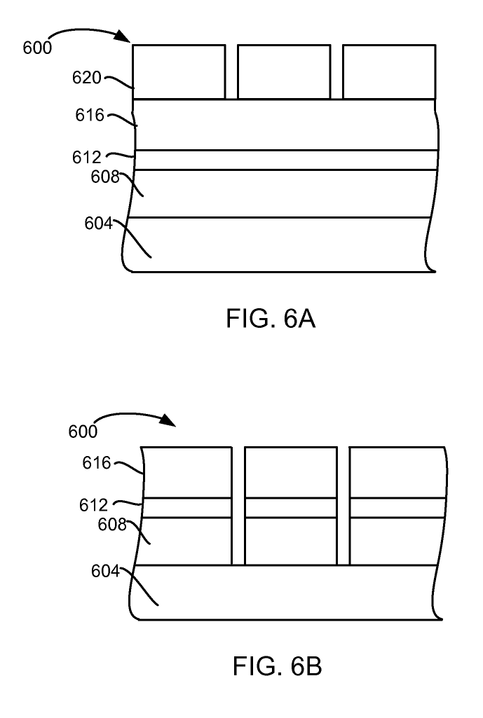

FIG. 6A is a cross sectional view of another stack 600, with a substrate 604 over which a first silicon nitride layer 608 is disposed, over which a silicon oxide based layer 612 is disposed, over which a second silicon nitride layer 616 is disposed, over which a photoresist mask is disposed 620. In this example, the first and second silicon nitride layers 608, 616 are in contact with the oxide based layer 612, which is several times thinner than the first and second silicon nitride layers 608, 616.

In this example, the selective silicon nitride etch with respect to the silicon oxide based material has a selectivity between 3:1 to 7:1. The selectivity is low enough to provide an etch of both the silicon nitride material layers and of the relatively thin silicon oxide layer. Such a recipe would use a lower percentage of hydrocarbon. For example, the nitride etch gas would be 5 sccm O₂, 180 sccm H₂, 60 sccm CF₄, 20 sccm CH₄, and 200 sccm Ar. In this example, the flow rate of CH₄ is less than the flow rate in the previous examples, which reduces selectivity. To form a plasma pressure is set to 80 mTorr. A signal of 50 watts at 27 MHz is provided. A signal of 450 watts at 60 MHz is provided.

FIG. 6B is a cross sectional view of the stack 600 after the first silicon nitride layer 608, the silicon oxide based layer 612, and the second silicon nitride layer 616 have been etched with a single etch step using this embodiment of the invention. An advantage of this embodiment is that all three layers may be etched with a single etch recipe.

In other embodiment, where a top silicon oxide based layer is used, if selectivity is too low, too much top oxide will be removed and the device will short out. In embodiments with a bottom oxide, if bottom oxide is exposed such as in a buried oxide scheme (BOX scheme), too low of a selectivity causes a risk that the etch will punch through to the underlying silicon and again short the device.

The various examples show the advantages provided by embodiments of the invention. The flow of the CH₄ or C₂H₄ provides a parameter to control the silicon nitride to silicon oxide selectivity. Generally, by increasing the flow of CH₄ or C₂H₄, the selectivity is increased.

Preferably, the nitride etch gas provides a flow ratio by volume of oxygen to CH₄ or C₂H₄ in the range of from 1:20 to 1:3. In addition, the nitride etch gas provides a flow ratio by volume of oxygen to hydrocarbon or hydrofluorocarbon in the range from 1:20 to 1:3. The ratio flow of CH₄ or C₂H₄ to the other reactants (in the previous examples, O₂, H₂, and CF₄, but not Ar, is in the range of 1:4 to 1:20. The flow of Ar is not factored into the ratio, since Ar in this recipe is not a reactant, but instead is a diluent. The forming the plasma from the nitride etch gas comprises maintaining a pressure between 40 to 200 mTorr, providing at least 50 watts of RF power at a frequency greater than 20 MHz.

The addition of a H₂ helps to prevent etch stop by preventing polymer buildup on the nitride surface during the selective etching. Because Hydrogen is many times lighter than the other etchants, it diffuses faster, making a uniform etch very difficult. The addition of a hydrocarbon, which is preferably CH₄ or C₂H₄, provides a uniformity above H₂ alone in preventing etch stop. In addition, the carbon from the hydrocarbon facilitates polymerization on the oxide surface to improve passivation. It has been unexpectedly found that the addition of CH₄ or C₂H₄ added to an etch chemistry with hydrogen and a hydrofluorocarbon, provides just the right amount of carbon for passivation of oxide, while providing a uniform hydrogen distribution to uniformly thin the passivation layer over the nitride. The CH₄ or C₂H₄ provides a tunable selectivity, with uniformity, without etch stop. Another way of measuring tuning may be according to the ratio of the flow rate of H₂ to the flow rate of CH₄ or C₂H₄. In the preferred embodiments, the molar flow rate of H₂ is greater than the molar flow rate of the fluorocarbon and hydrofluorocarbon species.

It has been found that the presence of oxygen is useful in rounding feature corners, which provides various advantages, such as making it easier to fill such features. Therefore, a preferred embodiment uses oxygen during the SiN etch. However, other embodiments of the invention may be oxygen free.

While this invention has been described in terms of several preferred embodiments, there are alterations, permutations, modifications, and various substitute equivalents, which fall within the scope of this invention. It should also be noted that there are many alternative ways of implementing the methods and apparatuses of the present invention. It is therefore intended that the following appended claims be interpreted as including all such alterations, permutations, and various substitute equivalents as fall within the true spirit and scope of the present invention.

What is claimed is:

1. A method for selectively etching a nitride layer with respect to a silicon oxide based layer over a substrate, comprising:
placing the substrate in a plasma processing chamber; and
etching the nitride layer, comprising:
flowing a nitride etch gas comprising a hydrocarbon species, an oxygen containing species, a hydrogen containing species, and a fluorocarbon or hydrofluorocarbon species into the plasma chamber;
forming an in situ plasma from the nitride etch gas in the plasma chamber; and
using the plasma from the nitride etch gas to selectively etch the nitride layer with respect to the silicon oxide based layer.

2. The method, as recited in claim 1, wherein the nitride layer is a silicon nitride layer.

3. The method, as recited in claim 2, where the hydrocarbon species is CH₄ or C₂H₄.

4. The method, as recited in claim 3, wherein the hydrogen containing species is H₂ and the oxygen containing species is O₂. and wherein a flow rate of H₂ is greater than a flow rate of the fluorocarbon and hydroflurorocarbon species.

5. The method, as recited in claim 4, wherein the selectively etching selectively etches that silicon nitride layer with respect to the silicon oxide based layer with a selectivity of at least 10:1.

6. The method, as recited in claim 5, wherein the fluorocarbon is CF₄, and wherein the nitride etch gas further comprises H₂ and Ar.

7. The method, as recited in claim 6, wherein the selective etching forms features in the silicon nitride with widths between 22 to 28 nm.

8. The method, as recited in claim 4, wherein the forming the plasma from the nitride etch gas comprises maintaining a pressure between 40 to 200 mTorr, providing at least 50 watts of RF power at a frequency greater than 20 MHz.

9. The method, as recited in claim 4, wherein the nitride etch gas provides a flow ratio by volume of CH₄ or C₂H₄ to all other reactants in the range of from 1:4 to 1:20.

10. The method, as recited in claim 4, wherein the silicon oxide based layer is sandwiched between silicon nitride layers, wherein the selectively etching selectively etches the silicon nitride layers with respect to the silicon oxide based layer with a selectivity between 5:1 to 7:1.

11. The method, as recited in claim 1, where the hydrocarbon species is CH₄ or C₂H₄.

12. The method, as recited in claim 1, wherein the oxygen containing species is O₂.

13. The method, as recited in claim 1, wherein the selectively etching selectively etches that silicon nitride layer with respect to the silicon oxide based layer with a selectivity of at least 10:1.

14. A method for selectively etching silicon nitride with respect to a silicon oxide based material forming a stack, comprising:
placing the stack in a plasma processing chamber; and
etching the silicon nitride, comprising the steps of:
flowing a silicon nitride etch gas into the plasma processing chamber, wherein the silicon nitride etch gas comprises hydrogen, a fluorocarbon or hydrofluorocarbon, and CH₄ or C₂H₄;
forming a plasma from the silicon nitride etch gas; and
using the plasma to selectively etch the silicon nitride with respect to the silicon oxide based material.

15. The method, as recited in claim 12, wherein the selectively etching selectively etches that silicon nitride layer with respect to the silicon oxide based layer with a selectivity of at least 10:1.

16. The method, as recited in claim 12, wherein the fluorocarbon or hydrofluorocarbon is CF₄, and wherein the silicon nitride etch gas further comprises O₂ and Ar.

17. The method, as recited in claim 12, wherein the forming the plasma from the nitride etch gas comprises maintaining a pressure between 40 to 200 mTorr, providing at least 50 watts of RF power at a frequency greater than 20 MHz.

18. The method, as recited in claim 12, wherein the nitride etch gas provides a flow ratio by volume of CH₄ or C₂H₄ to all other reactants in the range of from 1:4 to 1:20.

19. An apparatus for selectively etching a silicon nitride layer with respect to a silicon oxide based layer over a substrate, comprising:
a plasma processing chamber, comprising:
a chamber wall forming a plasma processing chamber enclosure;
a substrate support for supporting a wafer within the plasma processing chamber enclosure;
a pressure regulator for regulating the pressure in the plasma processing chamber enclosure;
at least one electrode for providing power to the plasma processing chamber enclosure for sustaining a plasma;
a gas inlet for providing gas into the plasma processing chamber enclosure; and
a gas outlet for exhausting gas from the plasma processing chamber enclosure;
a gas source in fluid connection with the gas inlet, comprising:
a CH₄ or C₂H₄ gas source;
a hydrogen gas source;
an oxygen gas source; and
a fluorocarbon or hydrofluorocarbon gas source; and
a controller controllably connected to the gas source and the at least one electrode, comprising:
at least one processor; and
computer readable media, comprising:
computer readable code for chucking the substrate to the wafer support;
computer readable code for flowing a selectively etching nitride etch gas into the plasma processing chamber, comprising:
computer readable code for flowing oxygen from the oxygen gas source into the plasma processing camber;
computer readable code for flowing fluorocarbon or hydrofluorocarbon gas from the fluorocarbon or hydrofluorocarbon gas source into the plasma processing chamber;
computer readable code flowing CH₄ or C₂H₄ gas from the CH₄ or C₂H₄ gas source into the plasma processing chamber; and
computer readable code for forming the selectively etching nitride etch gas into a plasma to selectively etch the silicon nitride layer with respect to the silicon oxide based layer.
